(19) United States
(12) Patent Application Publication
(10) Pub. No.: US 2016/0293695 A1
(43) Pub. Date: Oct. 6, 2016

(54) SEMICONDUCTOR DEVICE AND METHOD FOR MANUFACTURING THE SAME

(71) Applicant: INSTITUTE OF MICROELECTRONICS, CHINESE ACADEMY OF SCIENCES, Beijing (CN)

(72) Inventors: Jing Xu, Beijing (CN); Jiang Yan, Beijing (CN); Bangming Chen, Beijing (CN); Hongli Wang, Beijing (CN); Bo Tang, Beijing (CN); Zhaoyun Tang, Beijing (CN); Yefeng Xu, Beijing (CN); Chunlong Li, Beijing (CN); Mengmeng Yang, Beijing (CN)

(21) Appl. No.: 14/391,889

(22) PCT Filed: Aug. 15, 2014
(86) PCT No.: PCT/CN2014/084513

§ 371 Date: Oct. 10, 2014

(30) Foreign Application Priority Data
Jul. 16, 2014 (CN) 201410340090.9

(51) Int. Cl. H01L 29/06; H01L 21/02; H01L 29/78; H01L 21/762; H01L 21/306; H01L 29/161; H01L 21/764

(52) U.S. Cl. CPC H01L 29/0649; H01L 29/161; H01L 21/02532; H01L 21/764; H01L 21/762; H01L 21/30604; H01L 29/78

(57) ABSTRACT

The present disclosure provides a semiconductor device, comprising: a substrate having a first semiconductor material; a second semiconductor layer on the substrate; a third semiconductor layer on the second semiconductor layer and being a device formation region; an isolation structure on both sides of the third semiconductor layer and on the substrate; and an hollow cavity below the source and drain regions of the third semiconductor layer and between the isolation structure and the ends of the second semiconductor layer. Such a device structure of the present disclosure incorporate the respective advantages of the bulk silicon device and the SOI device, and has characteristics of lower cost, smaller leakage current, lower power consumption, fast speed, simple process and high integration level. Meanwhile, the floating body effect and the spontaneous heating effect are eliminated as compared with the SOI device. Furthermore, the lower dielectric constant in the hollow cavity results in that it may withstand a higher voltage.

### CROSS-REFERENCE TO RELATED APPLICATION(S)

This application claims priority to a Chinese Application No. 201410340090.9, filed on Jul. 16, 2014 and entitled “SEMICONDUCTOR DEVICE AND METHOD FOR MANUFACTURING THE SAME”, which is incorporated herein by reference in their entirety.

### TECHNICAL FIELD

The present disclosure relates to the semiconductor device field, and particularly, to semiconductor devices and methods for manufacturing the same.

### BACKGROUND

As the size of the device continues to be shrunk, the number of devices per unit area of a chip becomes much continuously, which leads to increase of dynamic power consumption. Meanwhile, the continuous shrinking of the size of the device leads to increase of leakage current, which in turn increases the static power consumption. When the semiconductor device is integrated in a high level and the channel length of a MOSFET becomes shorter continuously, a series of effects which may be neglected in a long channel model for a MOSFET becomes more significant, which even become a dominant factor affecting performance of a device. Such a phenomenon is generally called as a short channel effect. The short channel effect would deteriorate electric performance of a device, such as leading to decrease of the threshold voltage of the gate, increase of the power consumption and decrease of signal-to-noise ratio, and the like.

An SOI substrate is a substrate in which a silicon dioxide layer is embedded below the silicon. As compared with a bulk silicon device, the device formed by a SOI substrate may obviously reduce leakage current and power consumption to suppress the short channel effect, so such a device has a significant advantage. However, the cost for the SOI substrate is higher and it needs a larger device area to avoid a floating body effect, so it is difficult to meet the requirement of high integration of the device. In addition, since a silicon dioxide layer is embedded, the performance of heat dissipation is affected.

### SUMMARY

The object of the present disclosure is to solve at least one of technical defects mentioned above and to provide semiconductor devices and methods for manufacturing the same.

The present disclosure provides a semiconductor device, comprising: a substrate having a first semiconductor material; a second semiconductor layer on the substrate; a third semiconductor layer on the second semiconductor layer and being a device formation region; an isolation structure on both sides of the third semiconductor layer and on the substrate; a hollow cavity below the source and drain regions of the third semiconductor layer and between the isolation structure and the ends of the second semiconductor layer.

Alternatively, the substrate may be a bulk silicon substrate, the second semiconductor may be GeₓSi₁₋ₓ (0<x<1), and the third semiconductor layer may be a silicon.

Alternatively, the semiconductor device may further comprise an oxide layer on the surface of the semiconductor material which constitutes the hollow cavity.

Alternatively, the oxide layer may be further formed between the isolation structure and substrate as well as between the third semiconductor layer and the isolation structure.

The present disclosure further provides a method for manufacturing a semiconductor device, comprising steps of: providing a substrate having a first semiconductor material; forming a second semiconductor layer on the substrate, and forming a third semiconductor layer on the second semiconductor layer; removing a partial of the second semiconductor layer from one end of the second semiconductor layer to form an opening; forming an isolation structure on both sides of the third semiconductor layer and on the substrate; wherein the third semiconductor layer is a device formation region, and the opening is below the source and drain regions of the third semiconductor layer.

Alternatively, the substrate may be a bulk silicon substrate, the step of forming the second semiconductor layer and the third semiconductor layer may comprise: epitaxial growing the second semiconductor of GeₓSi₁₋ₓ on the substrate, 0<x<1; epitaxial growing the third semiconductor layer of silicon; and pattering the second semiconductor layer and the third semiconductor layer.

Alternatively, the step of removing a partial of the second semiconductor layer from one end of the second semiconductor layer to form an opening may comprise: selectively removing the second semiconductor layer by a wet etching so as to form an opening at ends of the second semiconductor layer.

Alternatively, the etchant for the wet etching may be a mixed solution of HF, H₂O₂, CH₃COOH and H₂O.

Alternatively, between the step of forming an opening and that of forming an isolation structure, the method may further comprise a step of forming an oxide layer in the inner walls of the opening.

Alternatively, the step of forming an oxide layer on the inner wall of the opening may comprise oxidizing to form an oxide layer on exposed surfaces of the substrate, the second semiconductor layer and the third semiconductor layer.

In the semiconductor device and the method for manufacturing the same provided by the embodiment of the present disclosure, a structure with a hollow cavity is formed below the source and drain region of the third semiconductor layer for the device and the semiconductor layer is below the channel region of the third semiconductor layer. Such a device structure incorporate the respective advantages of the bulk silicon device and the SOI device, and has characteristics of lower cost, smaller leakage current, lower power consumption, fast speed, simple process and high integration level. Meanwhile, the floating body effect and the spontaneous heating effect are eliminated as compared with the SOI device. Furthermore, the lower dielectric constant in the hollow cavity results in that it may withstand a higher voltage.

### BRIEF DESCRIPTION OF THE DRAWINGS

The above and/or additional aspects and advantages of the present disclosure become apparent and appreciated to be understood in the following description of the embodiments in conjunction with the accompany figures, in which

FIGS. 1-6 show schematic views of the semiconductor device at various stages according to embodiments of the present disclosure; and

FIG. 7 shows a flowchart of a method for manufacturing the semiconductor device according to an embodiment of the present disclosure.

### DETAILED DESCRIPTION

The embodiment of the present disclosure will be illustrated in detail below, the example of which is shown in the accompany figures and in which identical or similar reference signs are used to represent identical or similar elements or element having identical or similar functions throughout the description. The embodiment illustrated by referring to the accompany figures is exemplified, which is not to limit but to explain the present disclosure.

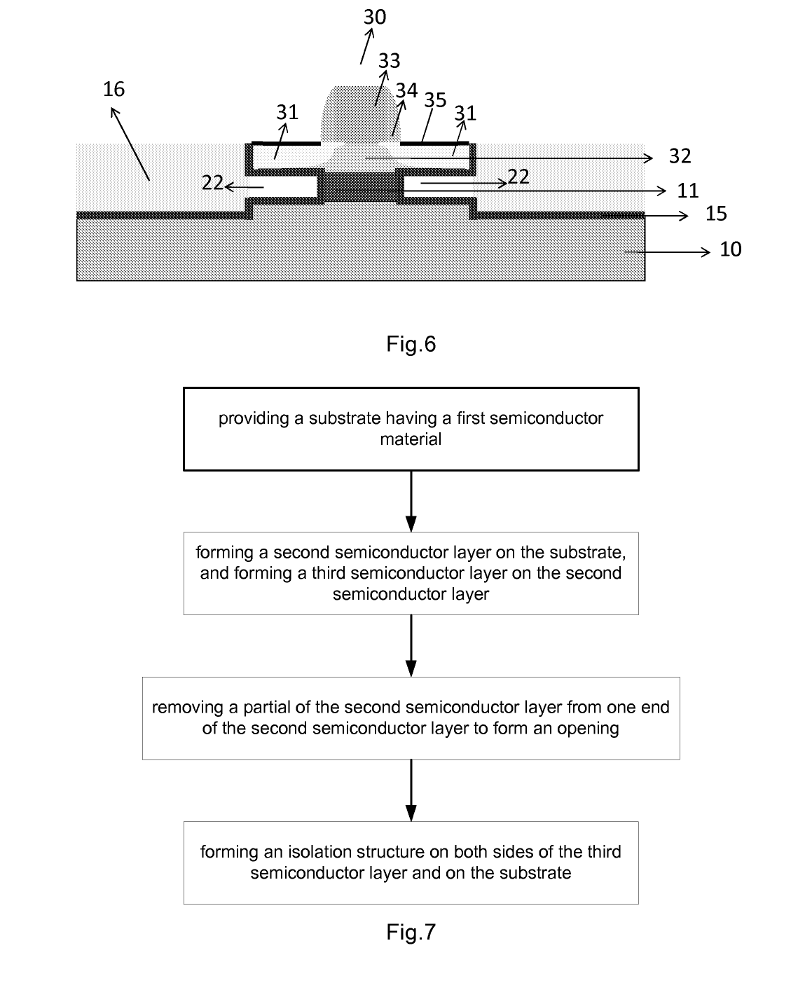

The object of the present disclosure is to provide a semiconductor device. As shown in FIG. 6, the semiconductor device may comprise: a substrate 10 having a first semiconductor material; a second semiconductor layer 11 on the substrate 10; a third semiconductor layer 12 on the second semiconductor layer 11 and being a device formation region; an isolation structure 16 on both sides of the third semiconductor layer 12 and on the substrate 10; a hollow cavity 22 below the source and drain regions 31 of the third semiconductor layer and between the isolation structure 16 and the ends of the second semiconductor layer 11.

In the present disclosure, the second semiconductor layer is formed on the substrate, and the third semiconductor layer for forming the device is on the second semiconductor layer. The second semiconductor layer is only formed below the channel region of the third semiconductor layer, and the structure of a hollow cavity is formed below the source and drain regions and between the second semiconductor layer and the isolation structure. Due to the presence of the hollow cavity, the leakage current and power consumption of the device is prominently reduced and the integrating level of the device is increased. As compared with a SOI device, the lower portion of the channel region being connected with the substrate has a better heat dissipation property and avoids generation of the floating body effect. Meanwhile, since a bulk silicon substrate may be employed for a device, the limitation of high cost of the SOI wafer is avoided. In addition, due to the lower dielectric constant for the air in the hollow cavity, the device may withstand a higher voltage.

Furthermore, the device of the present disclosure is applicable for a high radiation environment, such as a strategic weapon. Since there is not an insulating layer of silicon oxide below the channel, the area of the irradiation sensitive region is decreased and a portion of the electron hole pair caused by irradiation is released by adjusting the back gate, which avoids the floating body effect caused by the irradiation.

In the present disclosure, the material for the substrate, the second semiconductor layer and the third semiconductor layer may be chosen according to the requirements of manufacturing process and the device performance. The identical or different semiconductor materials may be employed. In a preferred embodiment of the present disclosure, the substrate may be a bulk silicon substrate, the second semiconductor may be GeₓSi₁₋ₓ (0<x<1), and the third semiconductor layer may be a silicon. Such a selection of this semiconductor material facilitates to form crystals for the second and third semiconductor layers by epitaxial growth, and the device will have an excellent property.

In addition, the oxide layer 15 is formed on the surface of the semiconductor material of the hollow cavity, i.e. the oxide layer is formed on the surface of the surface of the third semiconductor layer, the side surface of the second semiconductor layer and the surface of the substrate in the hollow cavity. Furthermore, the oxide layer 15 is formed between the third semiconductor layer 12 and the isolation structure 16 as well as between the substrate 10 and the isolation structure 16. The formation of such an oxide layer may eliminate the surface defects formed during the process such as etching so that the surface is planarized. The oxide layer 15 may be a ultra-thin oxide layer with a thickness of about 10-100 Å.

In addition, the present disclosure further provides a method for manufacturing the semiconductor device mentioned above. In order to better understand the technical solution and technical effect of the present disclosure, a particular embodiment will be illustrated in detail in conjunction with the flowchart of FIG. 7.

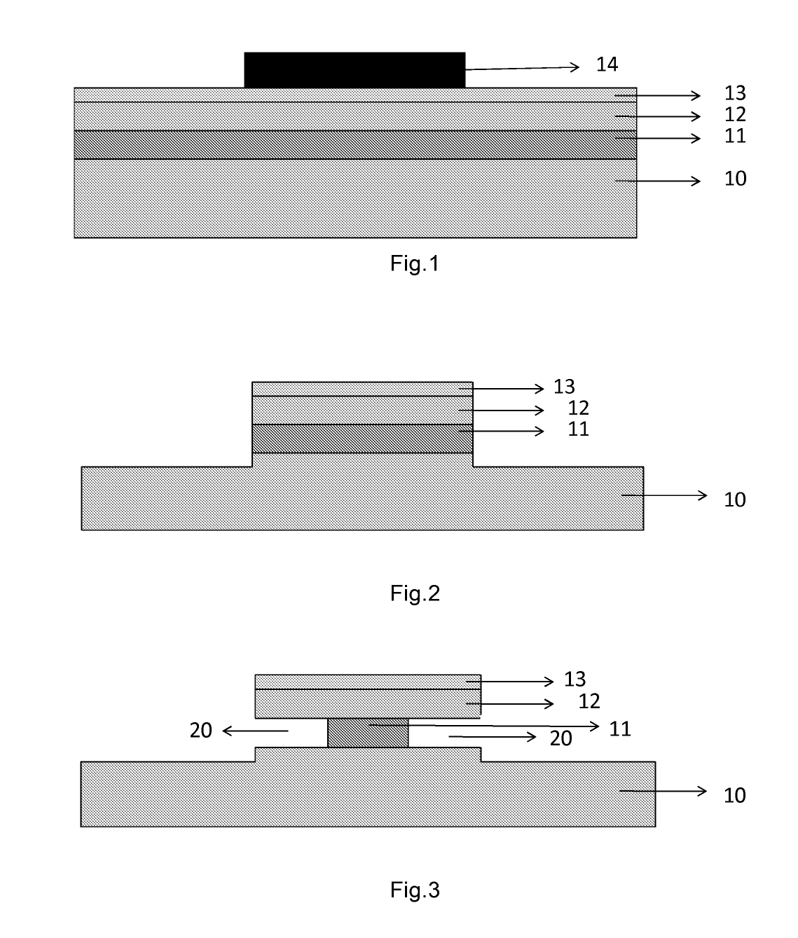

First of all, a substrate 10 having a first semiconductor material is provide, as shown in FIG. 1.

In the present disclosure, the substrate may be a semiconductor substrate. Preferably, the substrate may be a substrate of a singular semiconductor material or a duality substrate, such as Si substrate, Ge substrate, and SiGe substrate. The substrate may comprise a substrate of other element semiconductor or compound semiconductor, such as GaAs, InP or SiC and the like. In the present embodiment, the substrate is a bulk silicon substrate.

Next, a second semiconductor layer 11 is formed on the substrate, and the third semiconductor layer 12 is formed on the second semiconductor layer 11, as shown in FIG. 2.

In the present embodiment, first of all and as shown in FIG. 1, a second semiconductor material 11 of GeₓSi₁₋ₓ and a third semiconductor material 12 of silicon are epitaxial grown in order on a bulk silicon substrate 10. Then, a hard mask material, such as silicon nitride, is deposited on the third semiconductor material 12, and the photoresist is coated and etched to form a patterned hard mask 13. The photoresist is removed and the pattern of the hard mask is the active region for forming the device. Then, the etching continues under the covering of the hard mask 13 to form a patterned second semiconductor 11 and a patterned third semiconductor layer 12, as shown in FIG. 2.

Next, a partial of the second semiconductor layer is removed from one end of the second semiconductor layer 11 so as to form an opening 20, as shown in FIG. 3.

In the present embodiment, a partial of the second semiconductor layer 11 is selectively removed by a wet etching. In particularly, in one preferred embodiment, the etching agent may employ a mixed solution of HF with a concentration of 49%, H₂O₂ with a concentration of 30%, CH₃COOH with a concentration of 99.8% and H₂O, in a ratio of 1:18:27:8. The second semiconductor layer in the two ends is removed by controlling the etching time. That is to say, there is not a support of the second semiconductor layer below the source and drain regions of the active region, which is a hollow portion.

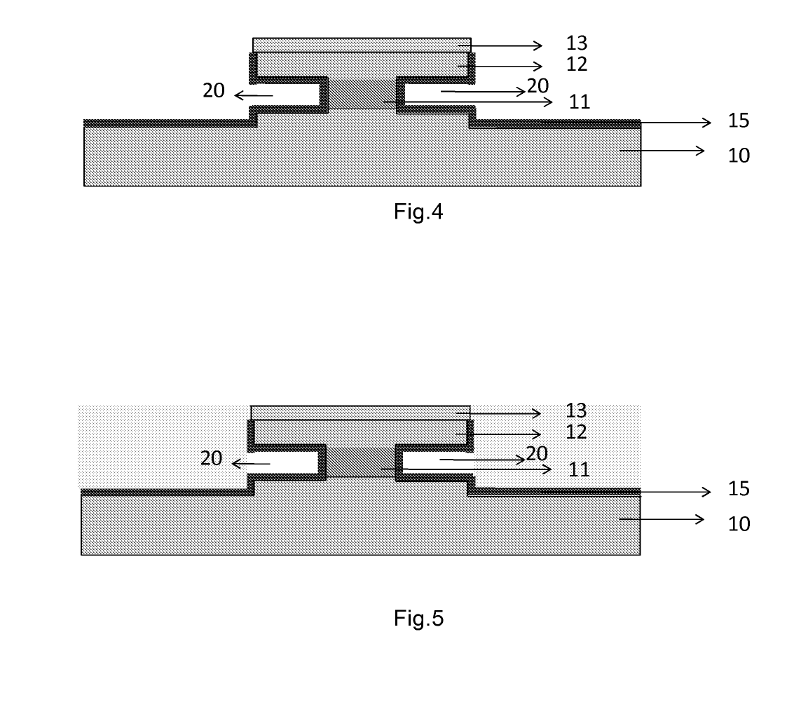

Next, an oxide layer 15 is formed in the inner walls of the opening 20, as shown in FIG. 4.

In the present disclosure, a ultra-thin oxide layer with a thickness of about 10-100 Å is formed by a dry oxidization, such as thermal oxidization. After the thermal oxidization, an oxide layer is formed on the exposed surface of the semiconductor material. That is to say, the oxide layer is formed on the inner wall of the opening, the substrate and the sidewalls of the third semiconductor layer, such that the defects formed on the surface of the semiconductor layer during the etching process is repaired and the exposed surface of the semiconductor material is more planar.

Next, an isolating structure 16 is formed on both sides of the third semiconductor layer 12 and on the substrate, as shown in FIG. 5.

In the present embodiment, the isolation structure 16 may be formed by a conventional process. Firstly, a dielectric material such as silicon oxide may be deposited. Then, a planarization such as Chemical Mechanical Polishing (CMP) is implemented until the surface of the hard mask 13 is exposed. Then, the hard mask 13 is further removed until the surface of the third semiconductor layer 12 is exposed to form the isolation structure 16 and the hollow cavity 22.

Next, the device is processed to form a semiconductor device 30 on the third semiconductor layer, as shown in FIG. 6.

The device may be formed by a conventional process. In the present embodiment, a CMOS device 30 is formed, as shown in FIG. 6. A well doping region 32 is formed in the second semiconductor layer 11 and the third semiconductor layer 12, and it may be formed in a partial of the substrate below the second semiconductor layer. A gate structure 33 is formed on the third semiconductor layer 12. A spacer 34 is formed on the sidewalls of the gate structure 33. Source and drain regions 32 is formed in the third semiconductor layer at both sides of the gate, and such source and drain regions 32 is on the hollow cavity 22. A metal silicide layer 35 is further formed on the source and drain regions 32. Next, the other components of the device are further formed, such as the contracts for the source and drain regions, the contact for the gate, the interconnecting structure and the like.

The illustration mentioned above is only the preferred embodiments of the present disclosure and is not intended to limit the present disclosure in any aspects.

Although the present disclosure is discloses by the preferred embodiment as mentioned above, it is not intended to limit the present disclosure. Those skilled in the art may make various change or modification to the technical solution of the present disclosure by utilizing the method and technique as disclosed above or modifies as an equivalent embodiment having substantial identical variation without departing from the scope of the present disclosure. Thus, any simple amendments, identical variation and modification to the above embodiment according to the technique of the present disclosure without departing from the technical solution of the present disclosure fall into the scope of the present disclosure.

I/we claim:

1. A semiconductor device, comprising:
a substrate having a first semiconductor material;
a second semiconductor layer on the substrate;
a third semiconductor layer on the second semiconductor layer and being a device formation region;
an isolation structure on both sides of the third semiconductor layer and on the substrate; and
a hollow cavity below the source and drain regions of the third semiconductor layer and between the isolation structure and the ends of the second semiconductor layer.

2. The semiconductor device according to claim 1, wherein the substrate is a bulk silicon substrate, the second semiconductor is GeₓSi₁₋ₓ, 0<x<1, and the third semiconductor layer is silicon.

3. The semiconductor device according to claim 1, further comprising an oxide layer on the surface of the semiconductor material which constitutes the hollow cavity.

4. The semiconductor device according to claim 3, wherein an oxide layer is further formed between the isolation structure and substrate as well as between the third semiconductor layer and the isolation structure.

5. A method for manufacturing a semiconductor device, comprising steps of:
providing a substrate having a first semiconductor material;
forming a second semiconductor layer on the substrate, and forming a third semiconductor layer on the second semiconductor layer;
removing a partial of the second semiconductor layer from one end of the second semiconductor layer to form an opening;
forming an isolation structure on both sides of the third semiconductor layer and on the substrate;
wherein the third semiconductor layer is a device formation region, and the opening is below source and drain regions of the third semiconductor layer.

6. The method according to claim 1, wherein the substrate is a bulk silicon substrate, the step of forming the second semiconductor layer and the third semiconductor layer comprising:
epitaxial growing the second semiconductor of GeₓSi₁₋ₓ on the substrate, 0<x<1;
epitaxial growing the third semiconductor layer of silicon on the second semiconductor layer; and
pattering the second semiconductor layer and the third semiconductor layer.

7. The method according to claim 6, wherein the step of removing a partial of the second semiconductor layer from one end of the second semiconductor layer to form an opening comprising:
selectively removing the second semiconductor layer by a wet etching so as to form an opening at ends of the second semiconductor layer.

8. The method according to claim 7, wherein the etchant for the wet etching is a mixed solution of HF, H₂O₂, CH₃COOH and H₂O.

9. The method according to claim 5, between the step of forming an opening and that of forming an isolation structure, further comprising a step of forming an oxide layer in the inner walls of the opening.

10. The method according to claim 9, wherein the step of forming an oxide layer in the inner walls of the opening comprising oxidizing to form an oxide layer on exposed surfaces of the substrate.
